(19) United States
(12) Patent Application Publication
(10) Pub. No.: US 2007/0238267 A1
(43) Pub. Date: Oct. 11, 2007

(54) Epitaxy of Silicon-Carbon Substitutional Solid Solutions by Ultra-Fast Annealing of Amorphous Material

(75) Inventors: Yaocheng Liu, Elmsford, NY (US); Oleg Gluschenkov, Poughkeepsie, NY (US); Anita Madan, Danbury, CT (US); Kern Rim, Yorktown Heights, NY (US); Judson R. Holt, Wappingers Falls, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/308,463

(22) Filed: Mar. 28, 2006

(51) Int. Cl. H01L 21/20; H01L 21/36

(52) U.S. Cl. 438/478; 438/486; 257/E21.054

(57) ABSTRACT

Expitaxial substitutional solid solutions of silicon carbon can be obtained by an ultrafast anneal of an amorphous carbon-containing silicon material. The anneal is performed at a temperature above the recrystallization point, but below the melting point of the material and preferably lasts for less than 100 milliseconds in this temperature regime. The anneal is preferably a flash anneal or laser anneal. This approach is able to produce epitaxial silicon and carbon-containing materials with a substantial portion of the carbon atoms at substitutional lattice positions. The approach is especially useful in CMOS processes and other electronic device manufacture where the presence of epitaxial Si_{1-y}C_{y}, y<0.1 is desired for strain engineering or bandgap engineering.

### BACKGROUND OF THE INVENTION

Crystalline alloys of silicon carbon (alone or possibly with other elements), e.g., Si_{1-y}C_{y}, y<0.1 where carbon is present as a substitutional solid solution (i.e., at lattice positions) is a very useful material for semiconductor device applications. For convenience, these alloys (optionally containing additional elements) will be referred to in this specification as “SC3S” materials. For example, SC3S can be employed for local strain engineering in semiconductor devices. SC3S can be also employed in bandgap engineering. In the strain engineering application, islands and/or layers of SC3S may be integrated (typically epitaxially) into a different crystalline material to beneficially alter the strain of that different crystalline material resulting in performance improvements of various semiconductor devices.

Local strain engineering techniques using lattice-mismatched crystalline stressors are particularly useful for sub-100 nm groundrule (nano-scale) advanced CMOS integrated circuits. There have been a number of proposals for different geometrical arrangements of SC3S structures for improving CMOS performance, e.g., U.S. Pat. No. 6,891,192, US20050082616, US20050104131, US20050130358, and Ernst et al., VLSI Symp., 2002, p 92; the disclosures of these references are incorporated herein by reference. A common geometrical feature of these structures is the localization of SC3S objects, e.g., as islands and/or layers of SC3S. There may be other applications for SC3S outside of CMOS integrated circuits, e.g., other types of integrated circuits and/or other applications outside the field of integrated circuits. These other applications may involve other geometries other than those mentioned above.

Regardless of the application, but especially in the context of integrated circuit devices and more especially in the context of CMOS integrated circuit devices, the challenge of SC3S is in its manufacture. The challenge is especially apparent in the context of epitaxial SC3S. The substitutional solid solubility of C in crystalline Si is extremely low. Therefore, it is very difficult to grow SC3S with high substitutional C concentration with traditional epitaxial (epi) growth techniques. This difficulty of producing SC3S is very fundamental in nature and is due to a large disparity between Si—Si and Si—C bonds in both binding energy and bond length. A substitutional C atom placed into Si crystalline lattice would highly distort the lattice causing a local increase in Gibbs free energy which, in turn, would limit incorporation of substitutional carbon into Si lattice in thermodynamic equilibrium.

Solid phase epitaxy (SPE) of amorphized silicon layers has been employed to “electrically activate” (place substitutionally into silicon lattice) implanted dopants such as B, As, P. Such SPE is carried out by annealing doped amorphous layers in a furnace at temperature of from 500° C. to 1300° C. for from 20 minutes to several hours or in a rapid thermal processor (RTP) from about 600° C. to 1200° C. for from 1 second to 180 seconds. Using these techniques to form SC3S is difficult. For example, attempts to produce SC3S by furnace-based SPE (e.g., 650° C., 30 minutes) have result in poor crystallinity and a low amount of carbon in substitutional lattice positions. In the case of attempts to make SC3S by RTP-based SPE (e.g., 1050° C., 5 sec), only about 0.2% substitutional carbon is incorporated into lattice. It has been generally accepted in the art that at high temperature only limited amount (less than about 1%) of substitutional carbon can be incorporated into silicon lattice.

Conventional low temperature non-localized epitaxial SC3S is extremely difficult in the low temperature range (T_{epitaxy}<700° C.) where less than 2% of substitutional carbon can be incorporated into the silicon lattice in a nonequilibrium state. Nonselective (ordinary) epitaxy process deposits crystalline, polycrystalline or amorphous material on entire substrate surface substantially impeding creation of localized structures from SC3S.

Accordingly, there is a continuous need for techniques suitable for fabricating localized structures of SC3S. Accordingly, there is a strong need for crystal-growing technique suitable for fabricating localized SC3S structures with substitutional C concentration in excess of 0.5% atomic percent and preferably in 1 to 4 atomic percent range.

### SUMMARY OF THE INVENTION

The invention utilizes ultra-fast annealing techniques of amorphous silicon and carbon-containing material such that the material is preferably exposed to temperatures at or above the recrystallization temperature, but below the melting point of such material, for a relatively short period of time. In this manner, SC3S materials can be created in a variety of structural configurations as may be desired in electronics manufacture or for other purposes.

In one aspect, the invention encompasses a method of forming SC3S structures, the method comprising:

(a) providing substrate having an amorphous region containing silicon and carbon atoms, and

(b) ultra-fast annealing the amorphous region to crystallize the region whereby at least a portion of the carbon atoms occupy lattice positions in crystalline material resulting in the region.

Preferably, the amount of substitutional carbon is about 0.5 to 10 atomic percent. Preferably, the annealing comprises heating the amorphous region to an annealing temperature above the recrystallization temperature of the material, but below its melting point for a very short time (e.g., less than 100 milliseconds). Preferred ultrafast annealing techniques are laser annealing and flash annealing, more preferably with a millisecond-scale characteristic anneal time (e.g., from about 5 milliseconds to about 50 microseconds). The amorphous region is preferably created in situ by amorphizing implant of a silicon material followed by an implant of carbon atoms. The sequence of these implantation steps can be accomplished in any order. Alternatively, the amorphous region can also be deposited amorphous Si—C mixture by chemical or physical vapor deposition or deposited amorphous Si followed by C implantation. Other suitable methods of introducing carbon atoms may also be used.

The invention also encompasses methods for forming NFET structures where the methods comprise:

(a) providing a substrate having an NFET gate stack over a semiconductor channel and at least one amorphous source/drain region containing silicon and carbon proximate to the channel, and

(b) ultrafast annealing the amorphous region to crystallize the region whereby at least a portion of the carbon atoms occupy lattice positions in crystalline material resulting in the region.

Preferably, the method involves making both source/drains of the NFET as SC3S regions. The invention also encompasses the formation of CMOS transistor structures and other integrated circuit structures incorporating SC3S.

These and other aspects of the invention are described in further detail below.

### BRIEF DESCRIPTION OF THE DRAWINGS

FIGS. 1(a)-1(d) show cross section views of examples of some possible SC3S configurations according to the invention.

FIGS. 2-4 show cross section views of an embodiment of the invention for manufacturing SC3S in a source/drain configuration associated with an NFET.

FIG. 5 shows a CMOS NFET-PFET pair with SC3S source drain regions about the NFET gate stack.

### DETAILED DESCRIPTION OF THE INVENTION

The invention is characterized in part by the use of ultra-fast annealing techniques to convert an amorphous silicon and carbon-containing material to SC3S. The ultra-fast anneal is preferably such that the amorphous material is quickly heated to a high temperature at which the recrystallization process occurs rapidly. The temperature is preferably at or more preferably well above the recrystallization temperature, but below the melting point of the material, only for a relatively short period of time. In preferred embodiments, the invention is further characterized by the creation of amorphous silicon- and carbon-containing material regions using (i) amorphization of a silicon-containing material on or in the substrate by implantation, followed by or preceded by (ii) implantation of carbon atoms into the amorphous region. These methods enable the obtaining of SC3S structures with high substitutional carbon concentration in a simple process at high anneal temperatures. The integration of SC3S structures into CMOS processes becomes very easy, especially using the preferred embodiments in part because amorphization, implantation, and solid phase epitaxy can be performed locally where desired.

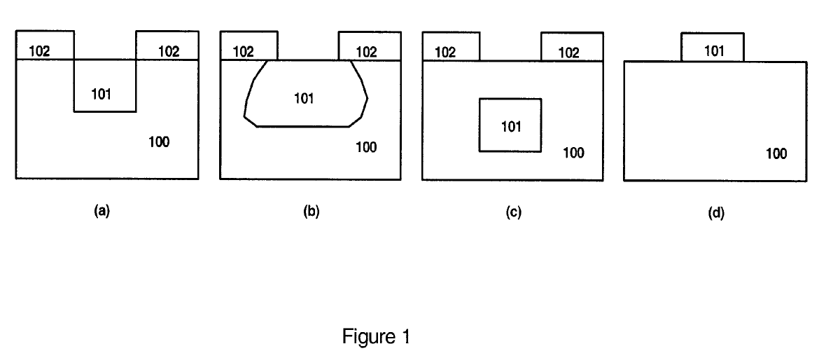

The invention can be used to create SC3S materials in a variety of structural configurations as may be desired in electronics manufacture or for other purposes. FIG. 1 shows some possible configurations (a)-(d) of SC3S structures which can be made using the methods of the invention. The invention is not limited to any specific SC3S structure or configuration. In FIG. 1(a), substrate 100 has an SC3S structure 101 that is aligned with mask 102 (the “mask” can be a permanent structure such as gate spacer or a sacrificial structure. FIG. 1(b) shows another example where the SC3S region 101 expands laterally under mask 102. FIG. 1(c) shows another example where the SC3S region 101 is formed as an island below the surface of substrate 100 where the location of the island is at least partially dictated by mask 102. In FIG. 1(d) the SC3S material 101 is present on the surface of substrate 100. The FIG. 1(d) structure can be formed by patterning a broader layer of SC3S structure or the precursor amorphous material using a mask (not shown).

The invention encompasses a method of forming SC3S structures, the method comprising:

(a) providing substrate having an amorphous region containing silicon and carbon atoms, and

(b) ultra-fast annealing the amorphous region to crystallize the region whereby at least a portion of the carbon atoms occupy lattice positions in crystalline material resulting in the region.

The invention is not limited to any particular method for forming the amorphous silicon and carbon containing material. For example, the amorphous silicon and carbon containing material can be formed by chemical or physical vapor deposition or other known technique for forming amorphous silicon layers.

Preferably, however, the amorphous silicon and carbon containing layer is formed by providing a silicon or silicon-containing substrate material target region where the SC3S is desired, rendering the target region amorphous by an amorphizing ion implantation (also known as a pre-amorphizing implant or PAI), and implanting the desired amount of carbon into the target region. The carbon may be implanted before or after the amorphizing step.

The amorphizing implantation species may be selected from those known in the art. Preferably, the amorphizing implantation species is selected from the group consisting of Si, Ge, As, Xe, Ar, Sb, P or other ions to amorphize the target silicon substrate location(s) to appropriate depth. PAI can be accomplished with the aid of a mask. In the NFET embodiment, the mask can be a part of the existing structure such as gate spacer or can be formed immediately prior to the implantation step using known photolithography and etching techniques. Examples of some possible PAI conditions, where Ge or As are used as amorphizing atoms, are implant energy of about 10-60 KeV with a dose of about 3E13-4E15 cm⁻². In some circumstances, the carbon to be implanted can create sufficient amorphization, especially if the implant temperature is reduced.

The carbon implant is preferably conducted with a dose of from 5E14 cm⁻² to 5E16 cm⁻² into the regions to achieve the desired carbon concentration. Preferably, the amount of carbon is sufficient to provide about 0.5 to 10 atomic percent carbon in the SC3S material, more preferably about 1 to 5 atomic percent carbon, most preferably about 1.2 to 4 atomic percent carbon. Dopants can also be implanted as needed or desired. If desired, the carbon may be implanted in only a part of amorphized region using an additional mask. Alternatively, if desired, the carbon concentration can be graded both vertically and/or laterally using well known implantation methods: such as by implanting a portion of carbon dose at higher energy and another portion of carbon dose at a lower energy; or implanting a portion of carbon dose at one tilt/twist implant angle set and another portion of carbon dose at another tilt/twist implant angle set.

In general, the SC3S lattice preferably contains at least about 80 atomic percent silicon in the lattice sites, more preferably at least about 90 atomic percent, most preferably about 95 to 99.5 atomic percent. The amount of dopant atoms (other than carbon or silicon) at lattice sites is preferably about 0 to 3 atomic percent. In addition, some of the lattice sites can be occupied by other elements such as germanium. If the silicon-containing material is an SiGe alloy, it preferably has a germanium content of about 50 atomic % or less, more preferably less than about 30 atomic %.

In general, it is preferable to avoid slow temperature ramp-up rate at or near the threshold temperature of recrystallization. Slow ramp-up rates will typically lead to recrystallization at lower temperature and generally to a product having little or no substitutional carbon remaining. Thus, the ramp-up from below the recrystallization temperature to the peak anneal temperature is preferably on the order of 50 nanoseconds to 10 milliseconds. The peak anneal temperature preferably is from 50° C. above the recrystallization temperature to just below the melting point for the material. The peak annealing temperature is preferably at least 900° C., more preferably at least 1100° C., most preferably about 1200-1350° C. The ultrafast anneal preferably has a limited duration in the target temperature regime i.e., the regime within about 100° C. below the peak temperature. Preferably, the duration is about 500 nanoseconds to 10 milliseconds, more preferably from about 0.5 microseconds to 1 millisecond, most preferably from about 5 microseconds to about 5 milliseconds.

Alternatively, the anneal duration can be measured at about full width half maximum (FWHM) of the heating energy pulse. For instance, a preferred anneal duration at measured FWHM of energy pulse is about 5 microseconds to 100 milliseconds, more preferably about 50 microseconds to 50 milliseconds, most preferably about 100 microseconds to 5 milliseconds. Preferably, the annealing is conducted in such a way that the amorphized regions are substantially fully recrystallized at or above about 900° C., more preferably above 1100° C., most preferably about 1100° C. to about 1300° C. Upon full recrystallization of the SC3S regions, the anneal can continue to a higher temperature, but preferably not above the Si melting point (1417° C.), more preferably not above 1390° C.

The energy in ultrafast anneal can be provided using any suitable method as long as the above annealing parameters are achieved. One useful example, the energy is delivered in the form of coherent optical radiation (i.e., laser radiation or a laser anneal). The laser source can operate in a pulsed or continuous wave (CW) mode. The laser beam can be shaped and polarized to allow for more uniform heating of the substrate. The lasing medium can be of different type (e.g. gas laser, solid state laser, dye laser, diode laser) yielding different wavelength of radiation. Further, if desired, one can add and shape extra layers on the wafer surface to aid energy coupling into the substrate. These auxiliary energy-coupling structures can be sacrificial or can be part of the substrate (e.g. printed in the substrate as part of the circuit layout). The invention is not limited to the type of laser, its mode of operation, its wavelength, the use of auxiliary energy-coupling structures, the laser beam shape, its polarization state, number of coherent sources used, coherence or absence thereof between multiple coherent laser source, and or other parameters of the laser anneal process as long as the amorphized regions are heated according to the time and temperature parameter values described above.

The energy for the ultrafast anneal can be also delivered in the form of incoherent radiation (lamp radiation). Such an anneal is referred to as the “flash anneal”. In another alternative, the energy in ultrafast anneal can be supplied via extremely hot gas jet (i.e., a jet anneal or torch anneal). Again, the exact method of coupling energy into the substrate is not so important to the instant invention as long as the amorphized regions are heated according to the time and temperature parameter values described above.

Once the recrystallization to for SC3S has occurred, it is preferred to quickly quench the system to freeze out the carbon atoms in the substitutional sites. In general, it is desirable to avoid excessive heating of the SC3S material and the entire wafer. If only a limited portion of the wafer is heated to the target temperature regime, the other portions of the wafer can dissipate the heat very quickly upon removal of the anneal energy. Thus, the desired quenching can be achieved in conventional tooling using this effect. Alternatively, it may be possible to introduce additional cooling measures to provide quenching. The cool down time should be as short as possible. The cool down time from the peak temperature (e.g., 1200-1350° C.) to 500° C. is preferably between 500 nanoseconds to 100 milliseconds.

A preferred ultra-fast anneal process and associated solid phase epitaxy (SPE) can be specified in terms of ramp-up and ramp-down rates above and below certain temperatures. A preferred ramp-up rate above about 500° C. is larger than about 10,000° C./second, more preferably from about 100,000° C./second to about 100,000,000° C./second, and most preferably from about to about 300,000° C./second to about 10,000,000° C./second. The preferred ramp-down rate from peak or target temperature to below about 500° C. is larger than about 5,000° C./second, more preferably from about 50,000° C./second to about 50,000,000° C./second, and most preferably from about to about 100,000° C./second to about 5,000,000° C./second.

The inventors conducted a series of experiments where SC3S was formed by laser annealing with temperature ramp-up rate of about million degrees per second and anneal duration at above about 1100° C. of less than about 300 microseconds. The anneal peak temperature was varied from about 1200° C. to about 1350° C. The SC3S samples were then analyzed using X-ray diffraction_(XRD) which showed that over 80% of the implanted carbon dose (1.8 atomic percent) was present as substitutional carbon (i.e., at lattice sites). XRD provides an accurate measure of the atomic spacing in the studied crystal. The amount of substitutional carbon was then inferred from the lattice spacing of the SC3S crystal. In this particular set of experiments, increasing peak anneal temperature from 1200° C. to 1350° C. did not result in any reduction of substitutional carbon because the anneal time was short enough preventing any “deactivation” of carbon atoms (i.e., migration from lattice to interstitial positions or forming silicon carbide compounds and clusters). In general, the invention preferably achieves an SC3S material where at least 60%, more preferably more than 80% of the implanted carbon dose is present as substitutional carbon.

Much shorter anneals with ramp-up rates higher than billion (1 e9) degrees per second and duration shorter than about 1 microsecond push silicon recrystallization threshold above silicon melt point leading to melting of amorphized areas. These conditions are generally not desired in the present invention.

The invention also encompasses methods for forming NFET structures where the methods comprise:

(a) providing a substrate having an NFET gate stack over a semiconductor channel and at least one amorphous source/drain region containing silicon and carbon proximate to the channel, and

(b) ultrafast annealing the amorphous region to crystallize the region whereby at least a portion of the carbon atoms occupy lattice positions in crystalline material resulting in the region.

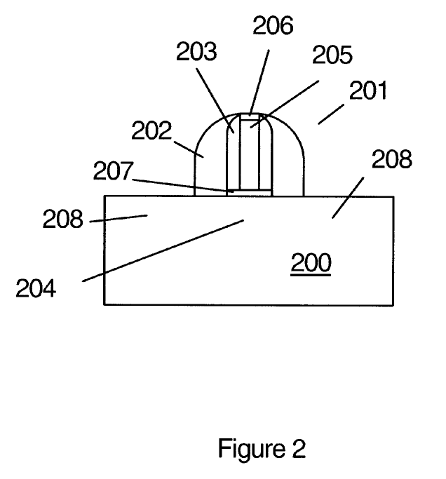

The general discussion above applies to the formation of SC3S in the context of NFETs. Referring to FIG. 2, an NFET gate stack 201 is provided over channel 204 in a semiconductor substrate 200. The invention is not limited to any particular NFET structure. The example NFET of FIG. 2 has two dielectric spacers 202 and 203 positioned on both sides of the gate stack (the spacers are only numbered on one side of the gate stack for ease of illustration). The example stack also has a gate electrode material 205, a cap dielectric 206 and a gate dielectric 207.

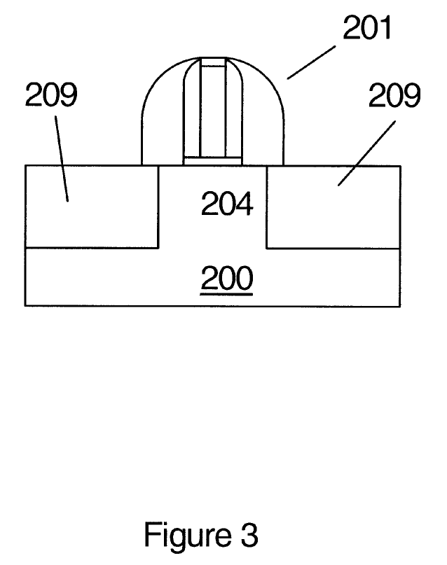

In FIG. 3, an amorphization implant is conducted to create amorphous areas 208 in the intended source/drain regions for the NFET. If desired, extension implantations may also be performed at this step. The desired carbon content and lateral and vertical profiles would also be provided by implantation as discussed above.

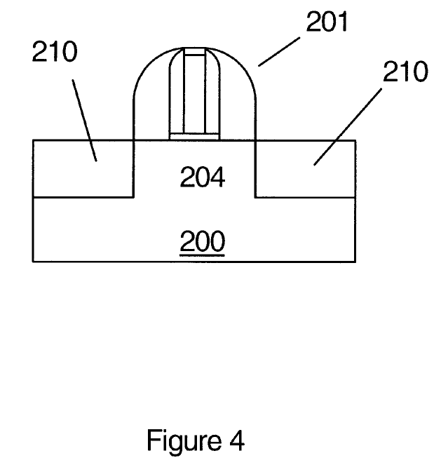

In FIG. 4, regions 208 are crystallized (solid-phase epitaxy) by laser anneal or flash anneal or other suitable technique as discussed above to form SC3S source/drain regions. This configuration of SC3S desirably acts as tensile stressors for the NFET channel region. The exact position of SC3S islands with respect to other geometrical features of the transistor can be adjusted by implantation conditions as alluded above. In one example, the SC3S islands can be submerged below the conductive surface of source/drain via carbon implants with retrograde carbon profiles.

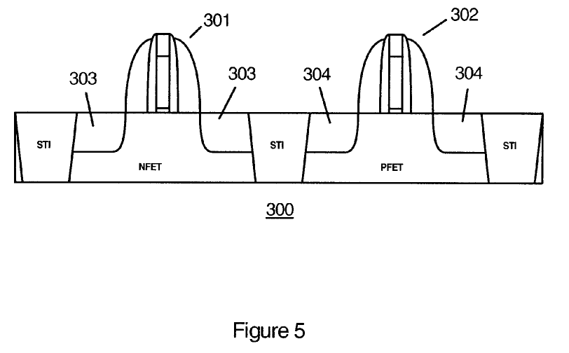

The invention also encompasses the formation of CMOS transistor structures and other integrated circuit structures incorporating SC3S. In a simple example of CMOS process flow, a conventional CMOS process can be used to form gate stack, spacers and extension, halo and source/drain doping for both PFET and NFET. FIG. 5 shows a substrate 300 with complementary NFET and PFET gate stacks 301, 302 with respective source/drain regions 303 and 304. A conventional RTA anneal may be conducted to diffuse dopants into polysilicon and to create required overlap between source/drain extensions and gate conductor edge. Following this, PAI and carbon implantation are conducted in the source/drain region of desired NFETs only. The PAI and C implantation are preferably controlled so that the PAI region and more than 60% of the implanted carbon are contained in the N+ source/drain doping region. The source/drain regions are then subjected to the ultra-fast anneal of the invention thereby forming the desired SC3S. Then, one can continue processing as desired. For example, if desired, one can integrate strain engineering of the PFET channel (using silicon germanium formed before or after the SC3S) into this the SC3S formation process of the invention whereby a strain engineered CMOS structure such as described in US Published Patent Application 2005/0082616A1 may be formed. The silicon germanium stressor described in US Published Patent Application 2005/0082616A1 could be formed before or after SC3S. Further, multiple thermal process steps can be conducted after formation of SC3S islands, but in such way that the thermal budget of such processes (temperature and time of the processes) avoids substitutional carbon deactivation in SC3S islands. For standard furnace and RTP thermal processes where the duration of anneals typically varies from hours to seconds, respectively, the temperature of such post SC3S anneals is preferably limited from about 450° C. to 600° C., respectively. However, additional ultra-fast anneals (as specified above) can be conducted after SC3S formation without much affect on the amount of substitutional carbon.

While the invention has been illustrated in the context of NFETs and CMOS devices, it should be understood that the SC3S formation techniques of the invention may be used in other contexts where SC3S structures are desired.

What is claimed is:

1. A method of forming epitaxial structures of silicon- and carbon-containing alloy, the method comprising:
(a) providing substrate having an amorphous region containing silicon and carbon atoms, and
(b) ultrafast annealing said amorphous region to crystallize said region whereby at least a portion of said carbon atoms occupy lattice positions in crystalline material resulting in said region.

2. The method of claim 1 wherein said amorphous region comprises about 0.5 to 10 atomic percent of carbon atoms.

3. The method of claim 2 wherein said amorphous region comprises about 1 to 4 atomic percent of carbon atoms.

4. The method of claim 1 wherein said annealing comprises heating said amorphous region to an annealing temperature above the recrystallization temperature of silicon and carbon-containing region, but below its melting point.

5. The method of claim 1 wherein said annealing comprises heating said amorphous region to an annealing temperature range of at least about 900° C.

6. The method of claim 5 wherein said annealing temperature range is at least 1100° C.

7. The method of claim 6 wherein said annealing temperature range is about 1200° C. to 1350° C.

8. The method of claim 4 wherein said annealing is such that said region is in said annealing temperature range for at least about 0.5 microseconds.

9. The method of claim 8 wherein said annealing comprises maintaining said region in said annealing temperature range for about 0.5 microseconds to 100 milliseconds.

10. The method of claim 1 wherein said annealing comprises a method selected from the group consisting of laser annealing and flash annealing.

11. The method of claim 1 further comprising heating up said region from below a recrystallization threshold temperature to a peak annealing temperature in about 50 nanoseconds to 10 milliseconds.

12. The method of claim 12 wherein said heating up is done at a rate ranging from about 10⁴° C./second to 10⁸° C./second.

13. The method of claim 1 further comprising cooling down said region from a peak annealing temperature to about 500° C. or below in about 500 nanoseconds to 100 milliseconds.

14. The method of claim 1 wherein said amorphous region comprises greater than 60 atomic percent silicon.

15. The method of claim 14 wherein said amorphous region further comprises atoms selected from the group consisting of Xe, Ar, P, Ge, As, Sb and combinations thereof.

16. The method of claim 1 wherein step (a) comprises depositing amorphous silicon-containing material on a substrate.

17. The method of claim 16 wherein said deposition is by chemical vapor deposition or physical vapor deposition.

18. The method of claim 1 wherein step (a) comprises (i) providing a substrate having at least one amorphous silicon-containing region and (ii) implanting carbon atoms into said region.

19. The method of claim 1 wherein step (a) comprises (i) providing a substrate having at least one crystalline silicon-containing region, (ii) treating said region to render it substantially amorphous, and (iii) implanting carbon atoms into said region.

20. The method of claim 19 wherein said treatment comprises implanting amorphizing atoms into said crystalline silicon-containing region.

21. The method of claim 20 wherein said amorphizing atoms are selected from the group consisting of Si, As, P, Ge, Sb, Ar and Xe.

22. A method of forming an NFET, said method comprising:
(a) providing a substrate having an NFET gate stack over a semiconductor channel and at least one amorphous source/drain region containing silicon and carbon proximate to said channel,
(b) ultrafast annealing said amorphous region to crystallize said region whereby at least a portion of said carbon atoms occupy lattice positions in crystalline material resulting in said region.

23. The method of claim 22 wherein step (a) further comprises providing a second amorphous source/drain region containing silicon and carbon proximate to said channel source/drain region semiconductor channel under said gate stack and step (b) comprises ultrafast annealing of both said regions whereby at least a portion of said carbon atoms occupy lattice positions in crystalline material resulting in each said region.

24. The method of claim 22 wherein said amorphous region comprises about 0.5 to 10 atomic percent of carbon atoms.

25. The method of claim 24 wherein said amorphous region comprises about 1 to 4 atomic percent of carbon atoms.

26. The method of claim 22 wherein said annealing comprises heating said amorphous region to an annealing temperature above the recrystallization temperature of said amorphous region, but below its melting point.

27. The method of claim 22 wherein said annealing comprises heating said amorphous region to an annealing temperature range of at least about 900° C.

28. The method of claim 27 wherein said annealing temperature range is at least 1100° C.

29. The method of claim 28 wherein said annealing temperature range is about 1200° C. to 1350° C.

30. The method of claim 26 wherein said annealing is such that said region is in said annealing temperature range for at least about 0.5 microseconds.

31. The method of claim 30 wherein said annealing comprises maintaining said region in said annealing temperature range for about 0.5 microseconds to 100 milliseconds.

32. The method of claim 22 further comprising heating up said region from below a recrystallization threshold temperature to a peak annealing temperature in about 50 nanoseconds to 10 milliseconds.

33. The method of claim 32 wherein said heating up is done at a rate ranging from about 10⁴° C./second to 10⁸° C./second.

34. The method of claim 22 wherein said annealing comprises a method selected from the group consisting of laser annealing and flash annealing.

35. The method of claim 22 further comprising doping said source/drain region before and/or during said ultrafast annealing step.

36. A method of forming a CMOS transistor structure, said method comprising:
(a) providing a substrate having an NFET gate stack over a semiconductor channel and at least one amorphous source/drain region containing silicon and carbon proximate to said channel,
(b) ultrafast annealing said amorphous region to crystallize said region whereby at least a portion of said carbon atoms occupy lattice positions in crystalline material resulting in said region, and
(c) providing a complementary pFET transistor.

37. The method of claim 36 further comprising doping said source/drain region before and/or during said ultrafast annealing.

38. The method of claim 36 wherein step (a) further comprises providing a second amorphous source/drain region containing silicon and carbon proximate to said channel source/drain region semiconductor channel under said gate stack and step (b) comprises ultrafast annealing of both said regions whereby at least a portion of said carbon atoms occupy lattice positions in crystalline material resulting in each said region.

39. The method of claim 36 wherein said amorphous region comprises about 0.5 to 10 atomic percent of carbon atoms.

40. The method of claim 39 wherein said amorphous said amorphous region comprises about 1 to 4 atomic percent of carbon atoms.

41. The method of claim 36 wherein said annealing comprises heating said amorphous region to an annealing temperature above the recrystallization temperature of silicon and carbon-containing region, but below its melting point.
